(19) United States
(12) Patent Application Publication
(10) Pub. No.: US 2024/0220204 A1
(43) Pub. Date: Jul. 4, 2024

(54) METHOD FOR CORRECTING DOT PRODUCT ERROR OF VARIABLE RESISTOR ARRAY

(71) Applicant: NANJING UNIVERSITY, Jiangsu (CN)

(72) Inventors: Feng MIAO, Jiangsu (CN); Shijun LIANG, Jiangsu (CN); Cong WANG, Jiangsu (CN); Yichen ZHAO, Jiangsu (CN)

(73) Assignee: NANJING UNIVERSITY, Jiangsu (CN)

(21) Appl. No.: 18/558,185

(22) PCT Filed: Sep. 23, 2022
(86) PCT No.: PCT/CN2022/120755

§ 371 Date: Oct. 30, 2023

(30) Foreign Application Priority Data
Nov. 18, 2021 (CN) 202111372955.6

(51) Int. Cl. G06F 7/544; G06F 17/16

(52) U.S. Cl. CPC G06F 7/5443; G06F 17/16

(57) ABSTRACT

Disclosed is a method for correcting a dot product error of a variable resistor array. The method includes: (1) initializing and writing a target conductance matrix into the variable resistor array; (2) calculating an effective conductance matrix of the variable resistor array; and (3) comparing the effective conductance matrix obtained in step (2) with the target conductance matrix, finishing executing the method in a case that a convergence condition is satisfied, and otherwise, continuing to execute steps as follows: multiplying a difference matrix by an adjustment coefficient η, such that an error conductance matrix is obtained; adjusting a conductance matrix G_{write} of actual variable resistors to G_{write}=G′_{write}− Gₑᵣᵣₒᵣ, where Gₑᵣᵣₒᵣ is the error conductance matrix, G′_{write} is a conductance matrix actually written into variable resistors last time; and executing steps (2) and (3) repeatedly after adjustment until a stop condition in step (3) is satisfied.

### TECHNICAL FIELD

The present invention relates to an in-memory calculating method based on a variable resistor array, and particularly relates to a method for correcting a dot product error of a variable resistor array.

### DESCRIPTION OF RELATED ART

When faced with a calculating task having high performance requirements, such as an artificial intelligence algorithm, a traditional storage and calculating separated architecture awfully reduces calculating efficiency. In-memory calculating can be achieved by means a variable resistor (including memristor, phase change memory (PCM), magnetic random access memory (MRAM), etc.) array. Different from the previous von Neumann calculating architecture, the in-memory calculating adopts analog signals such that a calculating process can be completed according to Kirchhoff's law and Ohm's law in a memory array. With enormous advantages in power consumption and speed, the in-memory calculating becomes a novel key research and development calculating architecture in the post-von Neumann era. With a cross array of variable resistors, dot product calculating of an input voltage vector and a conductance matrix of variable resistors can be achieved according to circuit characteristics, so matrix multiplication can be accelerated, and performance of a neural network can be improved. However, since an existing variable resistor array is generally limited to a manufacturing process and so on, a certain line resistance inevitably exists in circuit connection between the variable resistors in the array. According to the voltage division theorem of circuits, a non-ideal voltage drop is caused, and an output result of the variable resistors has a deviation. An influence of the line resistance increases with an increase in scale of a variable resistor array, and this deviation is extremely obvious if scale of a variable resistor array is larger than 128×128. Therefore, when we deploy a neural network on a large-scale variable resistor array, this non-ideal characteristic will enable output of the neural network to generate a deviation, which will affect the performance of the neural network, and may even cause complete failure of the neural network.

An existing technical solution is to reduce, generally by increasing a resistance of a variable resistor, a voltage divided to the line resistance, or to correct, by performing compensation at an output rear end of a variable resistor array, an output deviation of the variable resistor array caused by non-ideal factors such as the line resistance. The method of increasing a resistance of a variable resistor in the existing technical solution has limited effects. For one thing, a resistance range of the variable resistor is increased in a limited manner; and for another thing, the method still has the above problems when applied to a larger cross array of variable resistors. The solution of performing compensation at an output rear end of a variable resistor array will increase complexity of a system, and does not solve the problems at a source of the variable resistor array, such that a final compensation effect is limited by some conditions and does not satisfy requirements. For example, the correction solution has a limited ability to modify an output deviation when facing input and weight within a large dynamic range, and has a poor correction effect.

### SUMMARY

Objective of invention: in order to solve the above problems, the present invention provides a method for correcting a dot product error of a variable resistor array, which can obviously improve an effect of correcting a matrix calculating error caused by a line resistance in the variable resistor array.

Technical solution: the present invention employs a technical solution of a method for correcting a dot product error of a variable resistor array. The method includes steps as follows:
(1) initializing and writing a target conductance matrix into the variable resistor array;
(2) calculating an effective conductance matrix and an effective resistance matrix of the variable resistor array; and
Specifically, the step may include: applying at least m groups of mutually orthogonal voltage vectors Vᵢₙ to the variable resistor array, measuring corresponding n groups of output current vectors I′ₒᵤₜ, and calculating effective conductance matrix G_{effective} by using Vᵢₙ·G_{effective}=I′ₒᵤₜ.

The step may be as follows: calculating an effective conductance matrix and an effective resistance matrix of the variable resistor array through a circuit modeling and simulation method, which includes steps as follows:
step 2.1: establishing a circuit model of the variable resistor array, and obtaining circuit equation group A·I=Vᵢₙ of the variable resistor array in a case that a line resistance is considered, where A is a coefficient matrix, I is a vector composed of all node currents on the variable resistor array, and Vᵢₙ is m groups of mutually orthogonal input voltage vectors;
step 2.2: substituting a corresponding inverse matrix according to formula I=A⁻¹Vᵢₙ, such that output current vector I is obtained;
step 2.3: obtaining output current vector I′^{out} of the array by using vector I according to a current superposition law of a circuit; and
step 2.4: obtaining effective conductance matrix G_{effective} through an orthogonal voltage vector method.

(3) Comparing the effective conductance matrix obtained in step (2) with the target conductance matrix, finishing executing the method in a case that a convergence condition is satisfied, and otherwise, continuing to execute steps as follows:

multiplying a difference matrix by an adjustment coefficient η, such that an error conductance matrix is obtained; adjusting a resistance of each variable resistor on an actual hardware array according to the error conductance matrix, that is, adjusting conductance matrix G_{write} of actual variable resistors to G_{write}=G′_{write}− Gₑᵣᵣₒᵣ, where Gₑᵣᵣₒᵣ is the error conductance matrix, G′_{write} is a conductance matrix actually written into variable resistors last time; and executing steps (2) and (3) repeatedly after adjustment until a stop condition in step (3) is satisfied.

The convergence condition in step (3) is that an absolute value of each element in the difference matrix obtained by comparing the effective conductance matrix with the target conductance matrix is less than a set threshold.

When an algorithm fails to converge, an effective conductance obtained every time in step (2) is multiplied by a coefficient k, and the algorithm is converged by adjusting a value of the coefficient k.

The above method may be stored in a computer-readable storage medium in a form of a computer program product. The program executes steps of the foregoing method for correcting a dot product error of a variable resistor array.

Beneficial effects: compared with the prior art, the present invention has advantages as follows: the technology directly compensates and adjusts a conductance/resistance of any type of variable resistor array, instead of estimating and correcting a result after a calculating result is formed, such that the present invention has a better effect of correcting a dot product error of the variable resistor array. According to the technical solution, a conductance of the variable resistor array is reasonably adjusted under the condition that a line resistance exists in the array, such that an accuracy rate of dot product output of the variable resistance array is obviously improved. In addition, the technology further provides a brand-new conductance matrix gain method, which improves convergence and universality of an algorithm such that the technology can be used on a variable resistor array of any scale, and it is ensured that the algorithm can rapidly converge. Moreover, the method does not use any differential relation, and only uses a relatively simple gradient descent method, such that the method is more suitable for computer simulation and coding, reduces learning cost, and is more universal. The present invention can obviously improve an effect of correcting a matrix calculating error caused by a line resistance in the variable resistor array, and has wide application value and potential. When the technology is applied to a variable potentiometer array, an amount of communication data between the variable potentiometer array and a control device is greatly reduced due to a fast convergence speed of the algorithm, and energy consumption of the system is greatly reduced. The technology is applied to a memristor array, and due to fast convergence of the algorithm, the numbers of times of reading and writing of a memristor are greatly reduced, and service life is remarkably prolonged.

### BRIEF DESCRIPTION OF THE DRAWINGS

FIG. 1 is a typical circuit diagram of a memristor array in a case of considering an influence of line resistance R₀.

FIG. 2 is a flow block diagram of a method for correcting a dot product error of a variable resistor array according to the present invention.

FIG. 3 is a diagram showing a simulated analysis result of convergence of a conductance adjustment algorithm according to the present invention.

### DESCRIPTION OF THE EMBODIMENTS

The technical solution of the present invention is further described below with a typical variable resistor, that is, a memristor as an instance and in combination with accompanying drawings and examples.

### Example 1

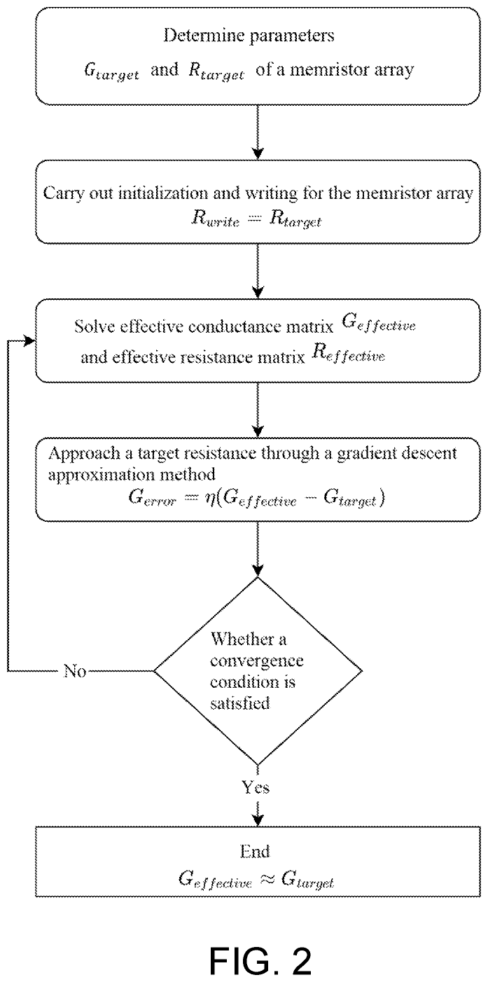

In actual hardware, an effective conductance matrix and an effective resistance matrix of a memristor array may be computed by measuring actual output of a memristor array. In this case, a flow of a method for correcting a dot product error of a variable resistor array in the present invention is as shown in FIG. 2, and includes steps as follows:

Step 1: determine a calculating parameter of a memristor array.

Target conductance matrix G_{target} to be written is converted to target resistance matrix R_{target}, where G_{target} is a conductance matrix specified in advance, and each element in R_{target} satisfies a reciprocal relation with an element in G_{target}. In cases of voltage vector Vᵢₙ input to the memristor array and current vector Iₒᵤₜ output from the memristor array, a calculating result of a memristor should satisfy relation Vᵢₙ·G_{target}=Iₒᵤₜ. The memristor array is initialized and subjected to reading and writing, and the written conductance matrix should satisfy G_{write}=G_{target} (that is, the resistance matrix satisfies R_{write}=R_{target}). In this case, an error exists between an effective conductance/resistance of an actual memristor array and a target conductance/resistance due to the existence of a line resistance, and adjustment is required to make the actual value close to the target conductance/resistance.

Step 2: calculate effective conductance matrix G_{effective} and effective resistance matrix R_{effective} of the memristor array.

As described in step 1, a voltage and a current satisfy formula Vᵢₙ· G_{target}=Iₒᵤₜ in dot product calculating of an ideal (regardless of a line resistance) memristor array. Since the conductance of the array is no longer ideal in non-ideal dot product calculating, Vᵢₙ. G_{effective}=I′ₒᵤₜ, where Vᵢₙ is a voltage input vector of 1×N, G_{effective} is the effective conductance matrix (that is, an equivalent conductance matrix in a case of considering a line resistance) of the memristor array, and I′ₒᵤₜ is a current output vector of 1×N, and has a different value from Iₒᵤₜ.

The value of I′ₒᵤₜ is a known quantity. In actual hardware, corresponding current output vector I′ₒᵤₜ may be obtained by measuring output of the array; but if software simulation is used, corresponding current output vector I′ₒᵤₜ may be obtained through circuit simulation or by listing a current equation of a circuit.

Therefore, Vᵢₙ and I′ₒᵤₜ are both known quantities, and effective conductance matrix G_{effective} is required to be solved. Different orthogonal voltage values are applied to the memristor array through the orthogonal voltage vector method, the corresponding current output is measured by an instrument, and data is transmitted to a special processing device, such that the effective conductance matrix is obtained. Equivalent conductance matrix G_{effective} is solved through an orthogonal voltage vector method, which is specifically as follows:

Assume that scale of the memristor array is m×n, where m is a length of input voltage vector Vᵢₙ, and n is a length of output current vector I′ₒᵤₜ. Input at least m groups of mutually orthogonal voltage vectors sequentially to the memristor array such that effective conductance matrix G_{effective} may be inversely derived from m groups of output current vectors.

For example, in a case that m orthogonal unit voltage vectors are taken as a base vector group, set first element V₁ of voltage vector Vᵢₙ as 1 and the other elements as 0, such that a group of voltage input vectors Vᵢₙ are obtained. Compute a value of a first row of conductance matrix G by formula Vᵢₙ·G_{effective}=I′ₒᵤₜ and by using the characteristic that only one element in Vᵢₙ is 1, where the value is exactly equal to I′ₒᵤₜ.

Then, set V₂ in Vᵢₙ as 1 and the other elements as 0, and obtain a second row of the conductance matrix according to the steps described above. Carry out similar steps until Vₙ is set as 1 and the other elements as 0, and obtain effective conductance matrix G_{effective} finally. Compute a reciprocal of each element in an equivalent conductance matrix, such that effective resistance matrix R_{effective} is obtained.

Step 3: approach a target resistance through a gradient descent approximation method.

Specifically, subtract effective conductance G_{effective} measured in the above step from target conductance G_{target}, finish executing the method in a case that an absolute value of each element in the obtained difference matrix is less than a preset threshold, and otherwise, continue to execute the remaining steps:
multiply the difference matrix by adjustment coefficient η (generally less than 1), such that error conductance matrix Gₑᵣᵣₒᵣ is obtained, and.
Gₑᵣᵣₒᵣ=η(G_{effective}−G_{target})

Adjust a resistance of each memristor on the array according to the error conductance matrix, that is, adjust a resistance of each memristor on an actual hardware array according to new conductance matrix G_{write} obtained through calculating; adjust the resistance by means of an existing voltage pulse sequence apparatus; enable a resistance adjustment process to satisfy formula G_{write}=G′_{write}− Gₑᵣᵣₒᵣ, where Gₑᵣᵣₒᵣ is an error conductance matrix, and G′_{write} is a conductance matrix actually written into the memristor last time; and execute steps 2 and 3 repeatedly after adjustment. Obtain, in a case that the stop condition in step 3 is satisfied, that G_{write} is the conductance matrix actually written into the memristor array, and written G_{effective} is approximately equal to G_{target}.

The above conductance adjustment method is suitable for most occasions, but if a line resistance between all devices in the memristor is over large, a maximum conductance to which the memristor array can be adjusted is Gₘₐₓ<G_{target}. In this case, the effective conductance of the array cannot be close to the target conductance no matter how many times of iterations are performed, and the algorithm cannot converge.

In order to solve this problem, gain parameter k(k>1) is introduced to apply a gain to the voltage. In standard memristor vector-matrix dot product calculating, Vᵢₙ·G=Iₒᵤₜ, and if gain k is applied to the voltage in calculating, kVᵢₙ· G=kIₒᵤₜ.

Moreover, Vᵢₙ·(kG)=Vᵢₙ·Gₖ=kIₒᵤₜ=Iₒᵤₜ^{new} is obtained by converting the above equation, which means that the gain applied to the voltage is equivalent to the gain applied to the conductance matrix of the array. Then kGₘₐₓ=Gₖ>G_{target} may be obtained by adjusting k. This means that after several times of iteration, the effective conductance of the array can be gradually increased to approach the target conductance, which solves the problem that the algorithm is difficult to converge in certain conditions.

This gain is added to the previous conductance adjustment algorithm, an effective conductance obtained every time in step 3 is G_{effective}=G_{effective}·k, and the algorithm may be converged by adjusting a value of k.

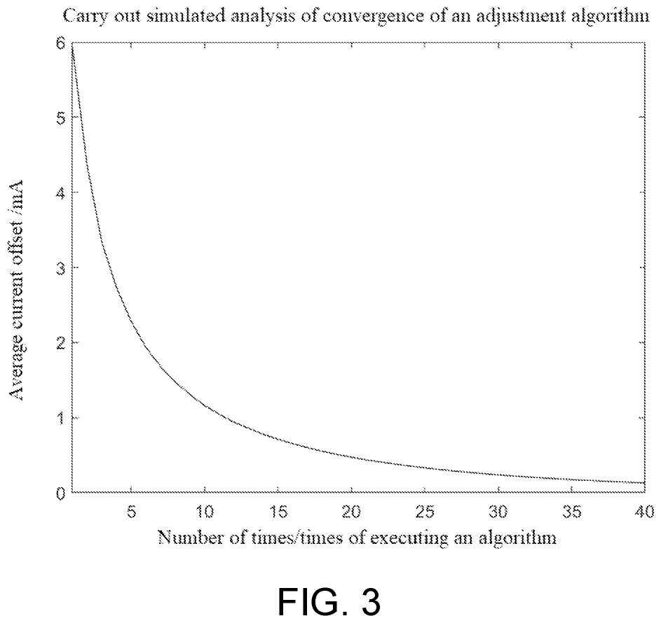

As shown in FIG. 3, the algorithm may converge in polynomial time, and a significant convergence effect is produced after about 10 times of execution. Compared with traditional neural network training adjustment, the algorithm has a faster convergence speed, no need of using data sets, and stronger usability.

### Example 2

A memristor array circuit may be simulated through software simulation, and an effective conductance/resistance matrix of a memristor array can be solved without actually measuring current output to know a current output vector. In this case, in the method for correcting a dot product error of a memristor array in the present invention, except that the method for specifically calculating effective conductance matrix G_{effective} and effective resistance matrix R_{effective} of the memristor array is different from that in Example 1, other steps are the same as those in Example 1. A specific implementation method of step 2 includes steps as follows:

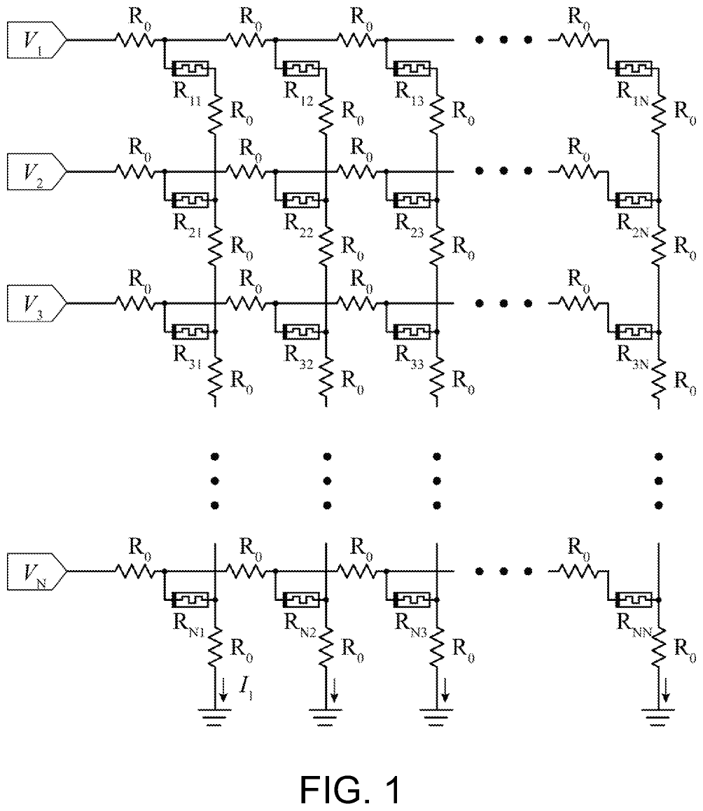

step 2.1: carry out modeling on a memristor array circuit, and establish a circuit equation group of the array under the condition that a line resistance in a circuit is required to be considered. A typical array circuit diagram is as shown in FIG. 1, and a total of N² of R₁₁, R₁₂, . . . , RNN memristor nodes (the array has N memristor nodes in each row and N memristor nodes in each column, and is an array of N rows and N columns), and known voltage input V₁, V₂, . . . , V_{N} and unknown current output I₁, I₂, . . . , I_{N} exist in the figure.

Assuming that current of any node Rₘₙ of the memristor is Iₘₙ, Iₘₙ is an unknown quantity of a solution required to be solved. Then, a current branch is selected according to voltage input row Vₙ and voltage output column Iₒᵤₜ, and it can be known that a voltage drop of the branch is certainly Vₙ, and the branch only includes one memristor node. According to the knowledge of the circuit, Vₙ is equal to a linear combination of unknown quantities of N² memristors and a corresponding coefficient (a dimension of which is resistance), and the corresponding coefficient α may be obtained by analyzing a circuit diagram. On this basis, N² N² branch equations may be listed, such that a circuit equation group is obtained.

A method for establishing a circuit equation group of an array is described with one node R₂₂ as an instance. The current branch V₂→R₀→R₀→R₂₂→R₀→R₀→ . . . →I₂ (at the end of the column) is selected, and therefore branch equations may be listed:

$${a}_{11}^{22} \cdot {I}_{11} + {a}_{12}^{22} \cdot {I}_{12} + … + {a}_{m n}^{22} \cdot {I}_{m n} + … + {a}_{n n}^{22} \cdot {I}_{n n} = {V}_{2}$$

Superscript 22 in a form of aₘₙ²² indicates that the equation is a branch equation listed with memristor R₂₂ as a core node, and subscript mn indicates that aₘₙ²² is a coefficient of current Iₘₙ flowing through memristor Rₘₙ in the mth row and the nth column.

According to N² memristor nodes, N² branch equations may be listed, and an array equation group of the circuit may be obtained.

Step 2.2: write an established equation group in form of A·I=Vᵢₙ according to knowledge of linear algebra, where A is a coefficient matrix, I is a vector composed of all node currents on the array, Vᵢₙ is an orthogonal voltage vector composed of input voltages on a right side of an equation set, and substitute a corresponding inverse matrix according to formula I=A⁻¹Vᵢₙ such that vector I may be obtained.

Step 2.3: obtain (column) output vector l′ₒᵤₜ of the array by using vector I according to a current superposition law of a circuit since vector I includes current information of all nodes on the memristor array, where a dimension of the vector is 1×N.

Step 2.4: traverse all possible orthogonal voltage vectors through the orthogonal voltage vector method in the present invention, and further obtain effective conductance matrix G_{effective} after current output vector l′ₒᵤₜ required through the orthogonal voltage vector method is obtained.

The above method for correcting a dot product error of a memristor array can be promoted to an array composed of other variable resistors, such as a phase change memory (PCM) array and a magnetic random access memory (MRAM) array.

Those skilled in the art should understand that examples of the present application can be provided as methods, systems, or computer program products. Therefore, the present application can employ full hardware examples, full software examples, or software and hardware combined examples. Moreover, the present application can employ a form of a computer program product implemented on one or more computer usable storage media (including, but not limited to, disc memories, compact disc read-only memories (CD-ROMs), optical memories, etc.) including computer usable program codes.

The present application is described with reference to flow diagrams and/or block diagrams of methods, devices (systems), and computer program products according to examples of the present application. It should be understood that each flow and/or block in the flow diagrams and/or block diagrams and combinations of the flows and/or blocks in the flow diagrams and/or block diagrams can be implemented by computer program instructions. These computer program instructions can be provided for a processor of a general-purpose computer, a special-purpose computer, an embedded processor, or other programmable data processing devices to produce a machine, such that instructions executed by the processor of the computer or other programmable data processing devices produce an apparatus configured to implement specified functions in one or more flows of each flow diagram and/or one or more blocks of each block diagram.

These computer program instructions can be stored in a computer readable memory that can guide a computer or other programmable data processing devices to work in a specific manner, such that the instructions stored in the computer readable memory produce an article of manufacture including an instruction apparatus, and the instruction apparatus implements specified functions in one or more flows of each flow diagram and/or one or more blocks in each block diagram.

These computer program instructions can be loaded onto a computer or other programmable data processing devices, such that a series of operations and steps are executed on the computer or other programmable devices to generate computer-implemented processing. Therefore, the instructions executed on the computer or other programmable devices provide steps for implementing specific functions in one or more flows in each flow diagram and/or one or more blocks in each block diagram.

1. A method for correcting a dot product error of a variable resistor array, comprising steps as follows:
(1) initializing and writing a target conductance matrix into the variable resistor array;
(2) calculating an effective conductance matrix of the variable resistor array and an effective resistance matrix of the variable resistor array; and
(3) comparing the effective conductance matrix obtained in step (2) with the target conductance matrix, stopping executing the method in a case that a convergence condition is satisfied, and otherwise, continuing to execute steps as follows:
multiplying a difference matrix, which is obtained by comparing the target conductance matrix with the effective conductance matrix, by an adjustment coefficient n, such that an error conductance matrix is obtained; adjusting a resistance of each variable resistor on an actual hardware array according to the error conductance matrix, that is, adjusting conductance matrix G_{write} of actual variable resistors to G_{write}=G′_{write}−Gₑᵣᵣₒᵣ, where Gₑᵣᵣₒᵣ is the error conductance matrix, G′_{write} is a conductance matrix actually written into variable resistors last time; and executing steps (2) and (3) repeatedly after adjustment until a stop condition in step (3) is satisfied.

2. The method for correcting the dot product error of the variable resistor array according to claim 1, wherein when an algorithm fails to converge, multiplying an effective conductance obtained every time in step (2) by a coefficient k, and the algorithm is converged by adjusting a value of the coefficient k.

3. The method for correcting the dot product error of the variable resistor array according to claim 1, wherein the convergence condition in step (3) is that an absolute value of each element in the difference matrix obtained by comparing the effective conductance matrix with the target conductance matrix is less than a set threshold.

4. The method for correcting the dot product error of the variable resistor array according to claim 1, wherein the step (2) of calculating the effective conductance matrix of the variable resistor array and the effective resistance matrix of the variable resistor array comprises: applying at least m groups of mutually orthogonal voltage vectors Vᵢₙ to the variable resistor array, measuring corresponding n groups of output current vectors I′ₒᵤₜ, and calculating the effective conductance matrix G_{effective} by using Vᵢₙ·G_{effective}=I′ₒᵤₜ.

5. The method for correcting the dot product error of the variable resistor array according to claim 1, wherein the step (2) uses a circuit modeling and simulation method to calculate the effective conductance matrix of the variable resistor array and the effective resistance matrix of the variable resistor array, which comprises steps as follows:
step 2.1: establishing a circuit model of the variable resistor array, and obtaining a circuit equation group A·I=Vᵢₙ of the variable resistor array in a case that a line resistance is considered, wherein A is a coefficient matrix, I is a vector composed of all node currents on the variable resistor array, and Vᵢₙ is m groups of mutually orthogonal input voltage vectors;
step 2.2: substituting a corresponding inverse matrix according to formula I=A⁻¹Vᵢₙ, such that output current vector I is obtained;
step 2.3: obtaining output current vector I′ₒᵤₜ of the array by using vector I according to a current superposition law of a circuit; and
step 2.4: obtaining the effective conductance matrix G_{effective} through an orthogonal voltage vector method.

6. A computer-readable storage medium, storing a computer program, wherein the computer program executes steps of the method for correcting the dot product error of the variable resistor array according to claim 1.
